(19) United States
(12) Patent Application Publication
(10) Pub. No.: US 2026/0198356 A1
(43) Pub. Date: Jul. 9, 2026

(54) METHOD FOR MANUFACTURING A SUBSTRATE FOR AN ELECTRONIC POWER OR RADIOFREQUENCY DEVICE

(71) Applicant: Soitec, BERNIN (FR)

(72) Inventor: Hugo Biard, BERNIN (FR)

(21) Appl. No.: 19/134,244

(22) PCT Filed: Dec. 5, 2023
(86) PCT No.: PCT/FR2023/051931

§ 371 Date: May 30, 2025

(30) Foreign Application Priority Data
Dec. 5, 2022 (FR) FR2212757

(51) Int. Cl. H10W 70/692; H10W 40/20; H10W 70/05; H10W 70/698

(52) U.S. Cl. CPC H10W 70/692; H10W 40/235; H10W 70/05; H10W 70/698

(57) ABSTRACT

A method for manufacturing a substrate for an electronic power or radiofrequency device includes: forming a support substrate comprising a deposition of at least one layer of polycrystalline silicon carbide by chemical vapor deposition (CVD) in an atmosphere comprising a mixture of argon and a deposition precursor fluidized in hydrogen, the chemical vapor deposition being carried out under Ar/(Ar+H₂) ratio and temperature conditions suitable for forming carbon inclusions in the layer of polycrystalline silicon carbide; and assembling the support substrate and a surface layer made of a monocrystalline material.

### CROSS-REFERENCE TO RELATED APPLICATIONS

This application is a national phase entry under 35 U.S.C. § 371 of International Patent Application PCT/FR2023/051931, filed Dec. 5, 2023, designating the United States of America and published as International Patent Publication WO 2024/121504 A1 on Jun. 13, 2024, which claims the benefit under Article 8 of the Patent Cooperation Treaty of French Patent Application Serial No. FR2212757, filed Dec. 5, 2022.

### TECHNICAL FIELD

The present disclosure relates to a substrate for an electronic device, in particular for application to radiofrequency or power electronics. The disclosure also relates to an electronic device comprising such a substrate, and to a method for fabricating such a substrate.

### BACKGROUND

Silicon carbide (SiC) is widely used for fabricating radiofrequency or power electronics components.

A substrate for producing such components typically comprises a support substrate, which may be made of polycrystalline SiC (p-SiC), and a surface layer of monocrystalline SiC (m-SiC) extending over the support substrate. Electronic components are fabricated in or on the monocrystalline SiC layer. The structure is cut out in the form of chips, each comprising one or more electronic components. Each chip is brazed to a thermal dissipation stack, comprising metal layers, a heat-conductive ceramic, and a heat sink.

The heat is thus removed mainly by the thermal dissipation stack, involving significant thermal stresses on the filler material bonding the electronic component and the upper metal layer of the thermal dissipation stack by brazing.

However, the coefficient of thermal expansion (CTE) and the Young's modulus of the SiC and the thermal stack, especially copper, are very different. Variations in temperature therefore lead to uneven deformations in the various layers above and below the braze. In particular, since the Young's modulus of SiC is high compared to that of the other materials, the stresses are concentrated in these other materials and in particular in the filler material.

Thus, the filler material is highly stressed, which leads to cracks, delaminations, or crumbling at the braze interface, resulting in a shortened device lifetime.

To reduce these mechanical stresses, it is known to thin down the layers of the composite structure, in particular, of the polycrystalline SiC base substrate. However, the abrasion of such a base substrate is long and laborious, resulting in a high cost of the electronic component. In addition, the thinning down involves a risk of breakage, rendering the composite structure unusable.

Another solution is to modify the materials used to carry out the brazing, which is difficult to implement, in particular, while preserving the mechanical solidity and the electrical and thermal conductivity of the brazing.

### BRIEF SUMMARY

An object of the disclosure is to propose a composite structure for the fabrication of electronic devices, exhibiting better resistance to temperature cycles, avoiding cracks, delaminations and crumbling at the brazing interface.

To this end, the disclosure proposes a method for fabricating a substrate for a radiofrequency or power electronics device, comprising:
forming a support substrate comprising deposition of at least one layer of polycrystalline silicon carbide by chemical vapor deposition, CVD, in an atmosphere comprising a mixture of argon and a deposition precursor that is fluidified in hydrogen, the chemical vapor deposition being carried out under Ar/(Ar+H₂) ratio and temperature conditions suitable for forming carbon inclusions in the silicon carbide layer, and
assembling the support substrate and a surface layer made of a monocrystalline material.

The CVD process under a gaseous atmosphere is an alternative to the known sintering process. The CVD process makes it possible to control the composition and morphology of the deposited layer. In particular, it may make it possible to create a concentration gradient of inclusions in a single deposition process.

The elongate silicon carbide grains are capable of generating an anisotropic electrical and thermal resistivity that is lower in a direction perpendicular to the surface of the substrate. This improves the removal of heat and the conduction of electricity toward the rear surface of the substrate. The presence of the carbon inclusions does not adversely affect the operation of the electronic device, which is fabricated in or on the monocrystalline surface layer, which is devoid of such inclusions.

Advantageously, the deposition precursor is methyltrichlorosilane.

Preferably, the surface layer is made of a semiconductor material, preferably of silicon carbide or of gallium nitride or of diamond.

Advantageously, at least a first phase of the chemical vapor deposition is carried out at a temperature of greater than 1200° C., preferably greater than 1400° C.

Advantageously, a first chemical vapor deposition start temperature is greater than a second chemical vapor deposition end temperature.

Preferably, the Ar/(Ar+H₂) ratio decreases during the chemical vapor deposition step.

Advantageously, the formation of the support substrate further comprises a step of assembling the at least one silicon carbide layer comprising the carbon inclusions with a base layer made of porous silicon carbide.

The disclosure also relates to a substrate for a radiofrequency or power electronics device, comprising:
a support substrate made of polycrystalline silicon carbide having a front face and a rear face, and
a surface layer made of monocrystalline material extending over the front face of the support substrate,
the substrate being characterized in that at least a portion of the support substrate comprises a plurality of silicon carbide grains having an elongated shape and oriented in a direction perpendicular to the surface of the substrate and a plurality of carbon inclusions located between the grains.

Preferably, the surface layer is made of a semiconductor material, preferably of silicon carbide or of gallium nitride or of diamond.

Advantageously, the ratio between the length and the width of the silicon carbide grains in the support substrate is greater than or equal to 1:1.2, advantageously greater than 1:10 and more advantageously greater than 1:20.

The ratio between the length and the width of the silicon carbide grains further facilitates polishing. Thus, if the polishing causes an elongate silicon carbide grain to be torn off in a direction perpendicular to the surface of the substrate, a cavity with reduced horizontal dimensions is obtained compared to the tearing off of a grain in an isotropic structure. In addition, tearing off is made more difficult because the grain is more deeply included within the matrix formed by the other grains.

Advantageously, the carbon inclusions are discontinuous.

Preferably, the ratio between the width and the length of the carbon inclusions is 1:1.2, advantageously greater than 1:20 and more advantageously greater than 1:30.

Advantageously, the support substrate exhibits a concentration gradient of the carbon inclusions, such that the density of the carbon inclusions increases from the front face toward the rear face.

In certain embodiments, only a portion of the support substrate comprises the carbon inclusions and the support substrate further comprises a portion devoid of carbon inclusions between the surface layer of monocrystalline SiC and the portion comprising the carbon inclusions.

Preferably, the volume ratio of the carbon inclusions in the support substrate is between 1% and 40%, preferably between 1% and 20%.

The disclosure also relates to an electronic device comprising a substrate as described above and at least one radiofrequency or power electronics component formed in or on the surface layer, and a heat removal device, the substrate being brazed to the heat removal device via a filler material such that the filler material is in integral contact with at least a part of the portion comprising carbon inclusions on the rear face of the support substrate.

### BRIEF DESCRIPTION OF THE DRAWINGS

Other features and advantages of the disclosure will become apparent from the detailed description, which follows, with reference to the appended drawings, in which:

FIG. 1 illustrates a device comprising two electronic components produced from a substrate according to the disclosure and a heat dissipation stack;

FIG. 2A illustrates a substrate according to a first embodiment;

FIG. 2B illustrates a substrate according to a second embodiment;

FIG. 2C illustrates a substrate according to a third embodiment;

FIGS. 3A to 3D illustrate the steps for producing a support substrate according to the disclosure;

FIGS. 4A to 4C illustrate the steps for assembling the support substrate with the surface layer; and

FIG. 5 is a graph of the various silicon carbide phases obtained during a CVD process as a function of the temperature and the gas composition in the deposition chamber.

### DETAILED DESCRIPTION

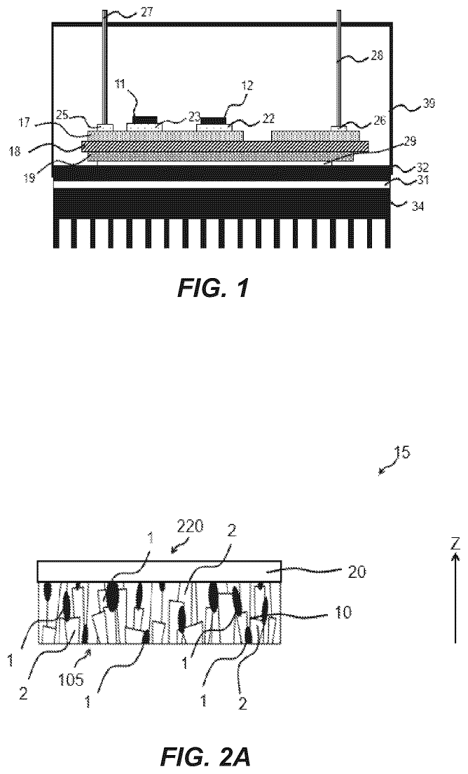

FIG. 1 illustrates a radiofrequency or power electronics device comprising one or more electronic chips 11, 12 produced from a substrate according to the disclosure. The chips may be connected via interconnections. In the case of a radiofrequency device, the electronic chip may carry a lateral gallium nitride device.

The electronic chips 11, 12 are mounted on a heat-dissipating structure by brazes 22, 23. This dissipating structure (DBC, acronym for “Direct Bonded Copper”) comprises two copper metallizations 17, 19 and a substrate 18 made of a thermally conductive and electrically insulating ceramic, for example, made of aluminum nitride. Electrical connections 27, 28 are fixed to the copper metallization 17 by way of brazes 25, 26.

A braze 29 fixes the device to a heat sink 34 and a base plate 32. A layer of thermal grease 31 ensures thermal contact between the heat sink 34 and the base plate 32. The radiofrequency or power electronics device is encapsulated in a package 39, which is typically made of plastic.

Each chip is formed from a substrate comprising a support substrate made of silicon carbide and a surface layer made of a monocrystalline material in or on which at least one power electronics component or radiofrequency electronics component is formed.

### Presentation of the Substrate

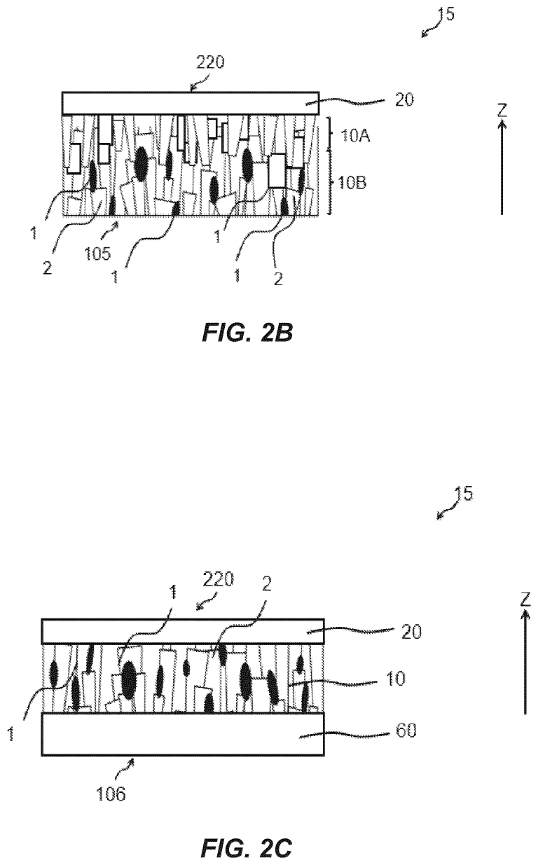

FIGS. 2A to 2C illustrate substrates 15 for a radiofrequency or power electronics device according to various embodiments. Each substrate 15 comprises, from its rear face to its front face, a support substrate 10 and a surface layer 20. The rear face 105, 106 of the support substrate 10 is intended to be fixed to the thermal stack 17, 18, 19 of FIG. 1 by a braze 22. One or more electronic components may be formed in or on the surface layer 20.

The support substrate 10 is made of polycrystalline silicon carbide. At least a part of the support substrate 10 comprises carbon inclusions 1. The silicon carbide is in the form of a plurality of elongate grains 2. The ratio between the width and the length of the grains 2 is greater than or equal to 1:1.2, and preferably greater than 1:10. In preferred embodiments, the ratio between the width and the length of the grains is greater than 1:20. The grains 2 are oriented in a Z direction perpendicular to the surface 220 of the substrate and are bonded together. The measurement and the variation of the grain size can be evaluated by counting the number of intersections between a line parallel to the base of the substrate and the grain boundaries. Such a measurement is, for example, carried out by a technical electron microscopy observation such as backscattered electron (BSE) microscopy.

The carbon inclusions 1 are dispersed discontinuously between the silicon carbide grains 2. The ratio between the width and the length of the carbon inclusions 1 is greater than or equal to 1:1.2, and preferably greater than 1:10. In preferred embodiments, the ratio between the width and the length of the carbon inclusions 1 is greater than 1:30.

The elongate geometry of the silicon carbide grains 2 and of the carbon inclusions 1 results in an improved electrical and/or thermal conductivity in a direction Z perpendicular to the surface 220 of the substrate compared to the conductivity perpendicular to Z, because the number of grain boundaries to pass through between the two faces is limited. Such a thermal conductivity in particular promotes a good removal of the heat toward a thermal stack bonded to the rear face 105 of the substrate by a braze.

With reference to FIG. 2A, the carbon inclusions 1 may be distributed throughout the extent of the support substrate 10. The distribution of the inclusions may be homogeneous. Alternatively, the support substrate exhibits a concentration gradient of the carbon inclusions. In this case, the density of the carbon inclusions decreases from the rear face toward the front face. The gradient may be implemented continuously, or successively in several layers having decreasing carbon levels from the rear face toward the surface.

In certain cases, with reference to FIG. 2B, a first portion 10A extending from the front face is devoid of carbon inclusions and a second portion 10B comprises inclusions, which may be distributed homogeneously or in a gradient.

Such a configuration has a front face of homogeneous composition, which facilitates the preparation of the support substrate for bonding a monocrystalline SiC layer. In particular, the grinding and/or polishing steps are easier to carry out on a homogeneous front face, since the carbon inclusions are more friable than the SiC grains. These inclusions are therefore more easily destroyed or torn off during polishing, which can lead to an increase in surface roughness.

For example, the second portion 10B comprising the inclusions may be a “thin” layer having a thickness of between 100 nm and 3 μm. In this case, the layer comprising the inclusions has very little impact on the thermal and electrical conductivity.

Alternatively, the second portion 10B comprising the inclusions is a “thick” layer, having a thickness that is, for example, approximately 350 μm. Such a layer enables the substrate to be thinned down via its rear face after the electronic components have been fabricated on its front face. For example, the layer may be thinned down to a final thickness of between 100 and 180 μm. This makes it possible to reduce the total resistance to the passage of a current flowing in the direction of an axis Z perpendicular to the base of the substrate.

For all of the thicknesses of the portion comprising the inclusions, and also for intermediate thicknesses between 3 and 100 μm, it is possible to prepare a starting second portion 10B having a thickness greater than the thickness envisaged for the final application, and to carry out thinning-down in a subsequent step.

In other embodiments, the substrate may comprise other additional layers. With reference to FIG. 2C, the substrate may comprise a porous silicon carbide layer 60 extending from its rear face 106. The substrate may comprise other layers having a porosity different from the porous silicon carbide layer 60, or one or more layers comprising inclusions obtained by a different method such as sintering, or consisting of another material.

A high carbon content makes it possible to reduce the Young's modulus of the silicon carbide and thus to bring the Young's modulus of the support substrate closer to the Young's modulus of a thermal stack on which the electronic component will be brazed. This makes it possible to avoid mechanical and thermal stresses in the substrate, especially at the rear face of the support substrate, and in the braze. The reduction in the stresses makes it possible to increase the lifetime of the component.

The volume ratio of the carbon inclusions in the support substrate is between 1% and 40%.

The thickness of the layer comprising the inclusions after deposition by CVD is typically between 500 μm and 4 mm, with variations in thickness (TTV, abbreviation for “total thickness variation”) that are typically between 50 μm and 1.5 mm.

After thinning down, the final thickness of the silicon carbide layer formed by CVD may vary depending on the application envisaged. For example, for a substrate diameter of 150 mm, the thickness of the layer comprising the inclusions is typically 350 μm±25 μm, and for a substrate diameter of 200 mm, the thickness of the layer comprising the inclusions is approximately 500 μm±25 μm.

The surface layer 20 is made of a monocrystalline material, for example, a semiconductor such as silicon carbide or gallium nitride or another semiconductor of the III-V type. In certain cases, the surface layer is made of diamond. In a preferred embodiment, the surface layer is made of monocrystalline silicon carbide. In a variant, the surface layer 20 may be a non-continuous layer, for example, a layer composed of a set of tiles, each of which is made of a monocrystalline material. This variant can be used for materials that are not available in the dimensions corresponding to the diameter of the support substrate. For example, the surface layer may be composed of a plurality of juxtaposed tiles made of diamond.

The function of the support substrate is to provide mechanical support for the component to be fabricated, and to efficiently dissipate heat toward the thermal stack. Furthermore, due to the anisotropy of the grains and carbon inclusions, the electrical conductivity perpendicular to the substrate surface is maximized because the number of grain boundaries to be passed through on the path is reduced.

### Fabrication Method

The steps of a method for fabricating such a substrate 15 will now be described. The method begins with the provision of a support 80 for the fabrication of the support substrate 10. Typically, use is made of a support 80 made of graphite that is easy to remove or burn off after the support substrate has been fabricated. The support 80 is introduced into a chemical vapor deposition (CVD) chamber and the chamber is heated to a first temperature T1. The first temperature T1 is greater than 1200° C., preferably greater than 1400° C. A high temperature T1 promotes the formation of carbon inclusions in the support substrate to be formed.

Simultaneously, a gas mixture is introduced into the deposition chamber. The gas mixture comprises a carrier gas, typically argon, and a deposition precursor fluidified by another gas, which is typically hydrogen. The precursor is, for example, methyltrichlorosilane (CH₃SiCl₃).

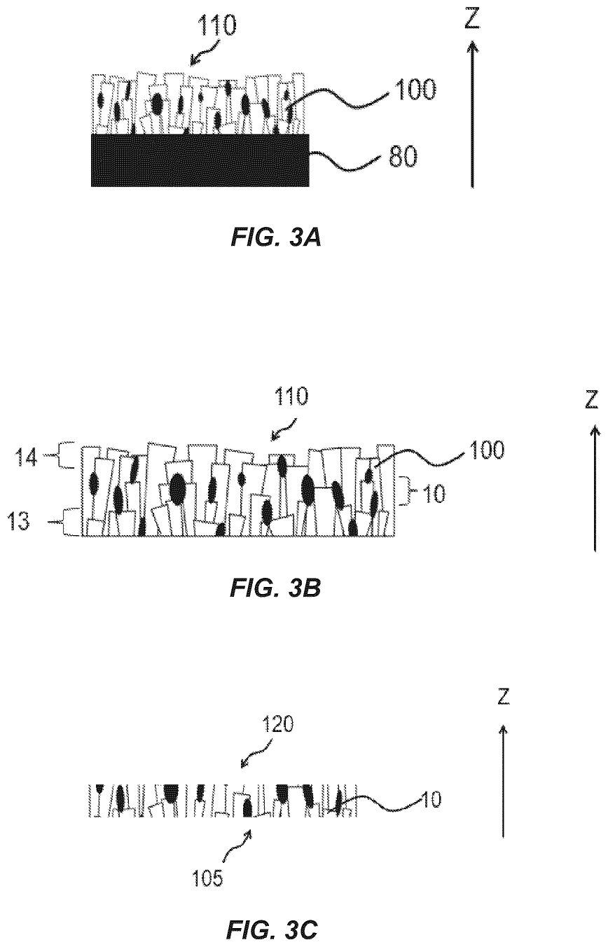

With reference to FIG. 3A, a layer 100 of silicon carbide comprising carbon inclusions is thus deposited on the support 80.

In the case where the aim is an upper layer devoid of inclusions or a gradient of inclusions (FIG. 2B), the temperature in the chamber is progressively lowered during the vapor deposition process to reach a deposition end temperature T2 that is lower than T1 and/or the Ar/(Ar+H₂) gas ratio is lowered.

In the case where a layer is deposited with a homogeneous distribution of inclusions (FIG. 2A), these parameters are kept constant.

The deposition of the silicon carbide layer is thus continued in order to obtain a thickness greater than the thickness of the support substrate to be fabricated. Typically, a thickness of between 500 μm and 2 mm is targeted.

At the start of the growth of the silicon carbide layer 100, the size of the grains is often variable and then becomes more homogeneous. By promoting the growth of a thick layer, the portion in which the grain size varies greatly can be subsequently removed, and the portion in which the grain size is homogeneous and of good crystal quality can be used. During and after the deposition, the surface 110 of the layer 100 has a high roughness because of the vertical orientation of the grains.

A substrate having silicon carbide in the form of a plurality of elongate grains is, for example, illustrated in FIGS. 3a to 3c of patent FR3134234. In the method according to the disclosure, silicon carbide grains having a similar structure are obtained. However, in order to form the carbon inclusions between the silicon carbide grains, the method according to the disclosure is carried out under determined conditions of temperature and argon content in the mixture of carrier gas and fluidification gas introduced with the precursor. The temperature is adjusted as a function of the argon content and is preferably greater than the temperature used in the method described in patent FR3134234, which also promotes a growth of silicon carbide in the form of elongate grains.

Such deposition conditions also cause the growth of carbon inclusions in the form of elongate grains. Advantageously, the ratio between the length and the width of the silicon carbide grains in the support substrate is greater than or equal to 1:1.2, advantageously greater than 1:10 and more advantageously greater than 1:20.

With reference to FIG. 3B, once the desired thickness of the silicon carbide layer 100 has been reached, the carbon support 80 is removed mechanically or by combustion.

With reference to FIG. 3C, the lower portion 13 of the silicon carbide layer in which the grain size is inhomogeneous and the crystal quality is worse than in the upper portion produced at the end of the deposition by CVD is then removed. A surface portion 14 having a high roughness or a high local variation in thickness on a scale larger than the roughness is also removed.

The removal of these excess portions 13, 14 is typically carried out by grinding followed by chemical mechanical polishing to achieve a flat surface 120 that is sufficiently smooth for the bonding of a surface layer. Such polishing uses a slurry containing abrasive particles in a chemically active mixture. Typically, after the removal steps, the thickness of the silicon carbide support substrate 10 is between 150 and 500 μm and may vary depending on the application envisaged. After subsequent thinning-down steps, the thickness is typically between 100 μm and 180 μm.

With reference to FIG. 3D, the support substrate 10 thus prepared is assembled with a surface layer 20 made of a monocrystalline material, typically via a process of the Smart Cut™ type.

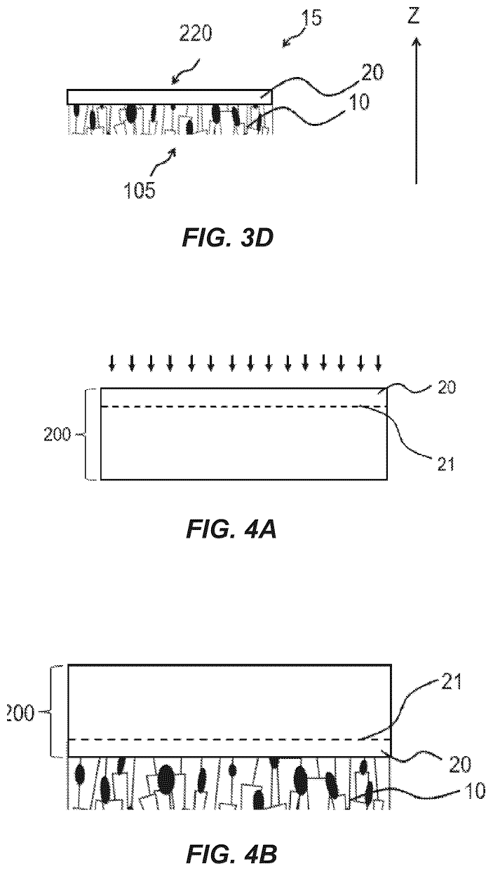

With reference to FIG. 4A, a monocrystalline donor substrate 200 is prepared for producing the surface layer 20. Cleaning and/or surface treatment may be applied to the surface of the donor substrate 200.

A weakened zone 21 is then formed in the donor substrate 200, so as to delimit a monocrystalline silicon carbide layer 20. The weakened zone 21 is formed in the donor substrate 200 at a predetermined depth that corresponds substantially to the thickness of the monocrystalline layer intended to form the surface layer of the support substrate for a radiofrequency or power electronics device to be formed. Preferably, the weakened zone 21 is created by implanting hydrogen and/or helium atoms into the donor substrate.

With reference to FIG. 4B, the donor substrate 200 is then bonded to the silicon carbide layer 10.

With reference to FIG. 4C, detachment of the donor substrate 200 is brought about along the weakened zone 21, so as to transfer the monocrystalline silicon carbide layer 20 onto the layer of silicon carbide comprising the carbon inclusions.

It is possible, before or after assembly with the monocrystalline silicon carbide layer 20, to assemble the support substrate 10 with other layers, for example, with a layer 60 of porous silicon carbide as illustrated in FIG. 2C.

From the finalized substrate, radiofrequency or power electronics components can be formed in or on the monocrystalline surface layer. The substrate is brazed onto a heat removal device. The brazing is carried out by providing a material, for example, silver, a silver-containing epoxy, gold-silicon, gold-tin, lead-tin, or a sintered material in the liquid phase, in integral contact with the lower face of the substrate. Thus, the filler material is in thermal contact with the carbon inclusions arranged at the rear face of the support substrate, which makes it possible to efficiently remove heat from the substrate toward the heat removal device.

### Formation of the Grains During the CVD Process

The use of a CVD process promotes the formation of grains in the silicon carbide and the formation of carbon inclusions. In addition, in contrast to a layer produced by sintering, deposition by CVD generally leads to anisotropic growth of the grains, such that their axis of maximum elongation extends parallel to the axis Z perpendicular to the base of the substrate. High anisotropy is desired for promoting the thermal and/or electrical conductivity along the axis Z.

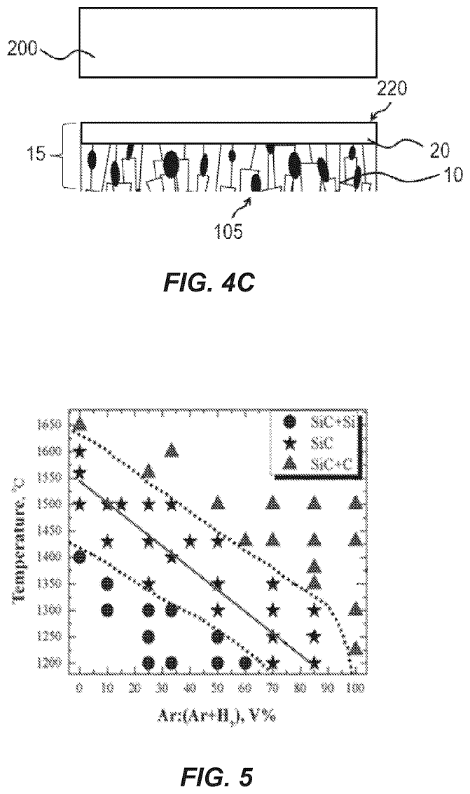

FIG. 5 is a representation of the various chemical compositions deposited as a function of the temperature and the gas composition in the deposition chamber. When the temperature and the ratio of the Ar/(Ar+H₂) gas are relatively low, a deposition of silicon carbide and pure silicon is obtained. For intermediate values of these two parameters, only silicon carbide is deposited. At high temperatures and with a high Ar/(Ar+H₂) gas ratio, silicon carbide and carbon are deposited. The operating conditions of the disclosure, therefore, correspond to the upper part of the phase diagram. In the temperature ranges shown, the amount of carbon is smaller than the amount of silicon carbide deposited, and the carbon is present in the form of inclusions in the silicon carbide layer. The ideal content for the formation of silicon carbide grains and carbon inclusions therefore depends on the temperature and atmosphere in the deposition chamber, in particular, on the ratio of the flow of carrier gas relative to the fluidification gas. The geometry and the size of the inclusions also depend on these parameters.

The CVD process for obtaining a two-phase deposition of silicon carbide comprising carbon inclusions is explained in detail in R. Liu et al.

The process of R. Liu et al. uses methyltrichlorosilane (CH₃SiCl₃) as precursor. The precursor is mixed with argon and gaseous hydrogen before the mixture of gases is introduced into the CVD deposition chamber. Depositions are carried out at various temperatures and various argon contents. The appearance and shape of the carbon inclusions are evaluated according to these parameters.

The appearance of the carbon inclusions depends on the Ar/(Ar+H₂) ratio and the deposition temperature. For example, for an Ar/(Ar+H₂) volume ratio of 25%, carbon inclusions appear starting from a temperature of 1560° C. For a volume ratio of 50%, carbon inclusions are formed at a temperature greater than or equal to 1500° C. In an argon environment without hydrogen, carbon inclusions can be formed starting from a deposition temperature of between 1200° C. and 1300° C.

By using ratios comprising a high argon content and a high temperature, a high concentration of inclusions is obtained. The volume ratio of the carbon in the substrate thus depends on the argon content and the temperature.

At a given temperature, it is also possible to reduce the grain size by increasing the argon content in the deposition chamber. In order to decrease the size of the carbon grains for a fixed carbon concentration, the temperature is lowered and the argon content is simultaneously increased.

The ratio between the width and the length of the carbon inclusions also depends on the temperature and on the Ar/(Ar+H₂) ratio.

In addition to obtaining an anisotropic structure, the deposition by CVD has other advantages over the formation of a two-phase structure by sintering. The use of a binder that may be polluting, especially in a clean room, is avoided. The control of the flow and mixing of the gases is also easy to master.

By lowering the temperature during the deposition by CVD with an adjustment of the Ar/(Ar+H₂) gas ratio, a concentration gradient of inclusions is achieved in a single deposition process. The reduction in temperature may be carried out in a continuous ramp in order to produce a continuous gradient for the concentration of inclusions.

Alternatively, the temperature may be lowered in steps in order to create layers in the substrate in which the content of inclusions decreases in discrete steps.

In an illustrative and non-limiting manner, it is possible to produce a concentration gradient of carbon inclusions over a thickness of 10 μm to 50 μm of the polycrystalline silicon carbide layer.

Typically, the initial concentration of the carbon inclusions of between 1% and 40% is decreased, such that the concentration of the inclusions is maximum at the start of the deposition and reaches a value of zero at the end of the deposition.

Such a reduction may be obtained by continuously decreasing the setpoint temperature during the growth of the SiC layer. The thermal dynamics of the known CVD machines make it possible to deposit a layer of SiC with such a gradient by carrying out a continuous deposition with modification of the temperature setpoint, without interrupting the deposition for possible cooling steps.

In order to obtain such a concentration gradient, it is also possible to decrease the argon content during the deposition, or to combine a decrease in temperature with a decrease in the argon content.

Alternatively, a first portion of the substrate may be produced by CVD deposition at a temperature and an argon content that bring about carbon inclusions. The argon content is subsequently greatly reduced and/or the deposition chamber is allowed to cool before carrying out a second deposition step in which the deposited layer consists of SiC without carbon inclusions. Thus, it is possible to produce a support substrate in which a first portion comprises carbon inclusions and a second portion is devoid of carbon inclusions. The monocrystalline SiC surface layer will then be transferred to the second portion devoid of carbon inclusions.

### REFERENCES

R. Liu et al.: Experimental phase diagram of SiC in CH₃SiCl₃—Ar—H₂ system, Journal of Materials Research August 2016-1(17):1-11.

FR3134234

1. A method for fabricating a substrate for a radiofrequency or power electronics device, comprising
forming a support substrate comprising deposition of at least one layer of polycrystalline silicon carbide by chemical vapor deposition (CVD) in an atmosphere comprising a mixture of argon and a deposition precursor that is fluidified in hydrogen, the chemical vapor deposition being carried out under Ar/(Ar+H₂) ratio and temperature conditions suitable for forming carbon inclusions in the at least one layer of polycrystalline silicon carbide; and
assembling the support substrate and a surface layer made of a monocrystalline material.

2. The method of claim 1, wherein the deposition precursor comprises methyltrichlorosilane (CH₃SiCl₃).

3. The method of claim 1, wherein the surface layer is made of a semiconductor material.

4. The method of claim 1, wherein at least a first phase of the chemical vapor deposition is carried out at a temperature of greater than 1200° C.

5. The method of claim 1, wherein a first chemical vapor deposition start temperature is greater than a second chemical vapor deposition end temperature.

6. The method of claim 1, wherein the Ar/(Ar+H₂) ratio decreases during the chemical vapor deposition.

7. The method of claim 1, wherein the formation of the support substrate further comprises assembling the at least one layer of polycrystalline silicon carbide comprising the carbon inclusions with a base layer made of porous silicon carbide.

8. A substrate for a radiofrequency or power electronics device, comprising
a support substrate made of polycrystalline silicon carbide having a front face and a rear face; and
a surface layer made of monocrystalline material extending over the front face of the support substrate;
wherein at least a portion of the support substrate comprises a plurality of silicon carbide grains having an elongated shape and oriented in a direction perpendicular to the surface layer of the substrate and a plurality of carbon inclusions located between the grains of the plurality of silicon carbide grains.

9. The substrate of claim 8, wherein the surface layer is made of a semiconductor material.

10. The substrate of claim 8, wherein the ratio between the length and the width of the silicon carbide grains in the support substrate is greater than or equal to 1:1.2.

11. The substrate of claim 8, wherein the carbon inclusions are discontinuous.

12. The substrate of claim 8, wherein the ratio between the width and the length of the carbon inclusions is greater than or equal to 1:1.2.

13. The substrate of claim 8, wherein the support substrate exhibits a concentration gradient of the carbon inclusions, such that the density of the carbon inclusions increases from the front face toward the rear face.

14. The substrate of claim 8, wherein only a portion of the support substrate comprises the carbon inclusions and the support substrate further comprises a portion devoid of carbon inclusions between the surface layer of monocrystalline SiC and the portion comprising the carbon inclusions.

15. The substrate of claim 8, wherein the volume ratio of the carbon inclusions in the support substrate is between 1% and 40%.

16. An electronic device, comprising:
a substrate according to claim 8;
at least one radiofrequency or power electronics component formed in or on the surface layer; and
a heat removal device, the substrate being brazed to the heat removal device via a filler material such that the filler material is in integral contact with at least a part of the portion comprising carbon inclusions on the rear face of the support substrate.

17. The method of claim 3, wherein the surface layer is made of silicon carbide or gallium nitride or diamond.

18. The method of claim 4, wherein the temperature greater than 1200° C. is greater than 1400° C.

19. The substrate of claim 10, wherein the ratio between the length and the width of the silicon carbide grains in the support substrate is greater than or equal to 1:10.

20. The substrate of claim 12, wherein the ratio between the width and the length of the carbon inclusions is greater than or equal to 1:20.
